(19) United States
(12) Patent Application Publication
(10) Pub. No.: US 2025/0160026 A1
(43) Pub. Date: May 15, 2025

(54) COMPLEMENTARY METAL OXIDE SEMICONDUCTOR IMAGE SENSOR WITH BARRIER DEVICE ISOLATION PATTERN

(71) Applicant: SAMSUNG ELECTRONICS CO., LTD., Suwon-si (KR)

(72) Inventors: Hyeonseop YOO, Suwon-si (KR); Jieun LEE, Suwon-si (KR)

(73) Assignee: SAMSUNG ELECTRONICS CO., LTD., Suwon-si (KR)

(21) Appl. No.: 18/904,782

(22) Filed: Oct. 2, 2024

(30) Foreign Application Priority Data
Nov. 10, 2023 (KR) 10-2023-0155032

(51) Int. Cl. H01L 27/146

(52) U.S. Cl. CPC H10F 39/807; H10F 39/011; H10F 39/182; H10F 39/80373; H10F 39/8063

(57) ABSTRACT

An image sensor includes a substrate including a pixel region, a first surface, and a second surface opposite to the first surface, a first photoelectric conversion region in the pixel region, a deep isolation pattern provided to at least partially penetrate the substrate and define the pixel region, a first transfer gate electrode in the pixel region and at least partially vertically overlapped with the first photoelectric conversion region, the first transfer gate electrode including a first upper portion, which protrudes above the first surface of the substrate, and a first lower portion, which is at least partially inserted into the substrate through the first surface of the substrate, a floating diffusion region in the pixel region and at least partially overlapped with the first photoelectric conversion region, and a barrier device isolation pattern between the floating diffusion region and the first transfer gate electrode.

### CROSS-REFERENCE TO RELATED APPLICATIONS

This application claims benefit of priority under 35 U.S.C. § 119 to Korean Patent Application No. 10-2023-0155032, filed on Nov. 10, 2023, in the Korean Intellectual Property Office, the disclosure of which is incorporated by reference herein in its entirety.

### BACKGROUND

### 1. Field

The present disclosure relates generally to an image sensor, and more particularly, to a complementary metal oxide semiconductor (CMOS) image sensor.

### 2. Description of Related Art

An image sensor may refer to a semiconductor device for converting an optical image to electrical signals. With the recent development of the computer and communication industries, there may be an increased demand for high-performance image sensors in a variety of applications such as, but not limited to, digital cameras, camcorders, personal communication systems, gaming machines, security cameras, micro-cameras for medical applications, robots, or the like. The image sensor may be classified into two types for example, a charge coupled device (CCD) type and a complementary metal-oxide-semiconductor (CMOS) type. In general, a CMOS-type image sensor may be referred to as a contact image sensor (CIS). A CIS device may include a plurality of two-dimensionally (2D) arranged pixels. Each of the plurality of pixels of the CIS device may include a photodiode (PD) that may convert an incident light into an electrical signal. The plurality of pixels may be defined by a deep isolation pattern disposed therebetween.

### SUMMARY

One or more example embodiments of the present disclosure provide an image sensor that is configured to reduce an interference issue between a floating diffusion region and a transfer gate.

Further, one or more example embodiments of the present disclosure provide an image sensor that includes a transfer gate and has a relatively low signal loss, when compared to related image sensors.

According to an aspect of the present disclosure, an image sensor includes a substrate including a pixel region, a first surface, and a second surface opposite to the first surface, a first photoelectric conversion region in the pixel region of the substrate, a deep isolation pattern provided to at least partially penetrate the substrate and define the pixel region, a first transfer gate electrode in the pixel region of the substrate and at least partially vertically overlapped with the first photoelectric conversion region, the first transfer gate electrode including a first upper portion, which protrudes above the first surface of the substrate, and a first lower portion, which is at least partially inserted into the substrate through the first surface of the substrate, a floating diffusion region in the pixel region of the substrate and at least partially overlapped with the first photoelectric conversion region, and a barrier device isolation pattern between the floating diffusion region and the first transfer gate electrode. The first transfer gate electrode is at least partially extended into the substrate. The barrier device isolation pattern is spaced apart from the first transfer gate electrode. A central intervening region is provided in the substrate to be at least partially vertically overlapped with the floating diffusion region.

According to an aspect of the present disclosure, an image sensor includes a substrate including a pixel region, a first photoelectric conversion region in the pixel region of the substrate, a deep isolation pattern provided to at least partially penetrate the substrate and at least partially enclose the pixel region, a shallow isolation pattern provided to be in contact with the deep isolation pattern and define an active portion of the substrate, a first transfer gate electrode and a second transfer gate electrode in the pixel region of the substrate and at least partially vertically overlapped with the first photoelectric conversion region, a floating diffusion region at least partially overlapped with the first photoelectric conversion region, and a barrier device isolation pattern between the floating diffusion region and the first transfer gate electrode and the second transfer gate electrode. The barrier device isolation pattern is spaced apart from the first transfer gate electrode and the second transfer gate electrode. A level of a bottom surface of the barrier device isolation pattern is higher than a level of a bottom surface of the shallow isolation pattern.

According to an aspect of the present disclosure, an image sensor includes a substrate including a plurality of pixel regions, a first surface, and a second surface opposite to the first surface, a transfer gate electrode in the first surface of the substrate and at least partially extended into the substrate, a plurality of photoelectric conversion regions provided in the plurality of pixel regions, a micro lens provided on the first surface and at least partially overlapped with the plurality of photoelectric conversion regions, a deep isolation pattern interposed between the plurality of pixel regions and at least partially extended from the first surface into the substrate, a shallow isolation pattern provided to be in contact with the deep isolation pattern and define an active portion of the substrate, a floating diffusion region in the plurality of pixel regions and spaced apart from the plurality of photoelectric conversion regions, a barrier device isolation pattern interposed between the floating diffusion region and the transfer gate electrode, and an interconnection layer in the first surface of the substrate. The barrier device isolation pattern is spaced apart from the floating diffusion region. A level of a bottom surface of the barrier device isolation pattern is lower than a level of a bottom surface of the floating diffusion region.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram illustrating an image sensor, according to an embodiment;

FIG. 2 is a circuit diagram illustrating a unit pixel of an image sensor, according to an embodiment;

FIG. 3A is a plan view illustrating an image sensor, according to an embodiment;

FIG. 3B is a sectional view taken along a line A-A′ of FIG. 3A to illustrate an image sensor, according to an embodiment;

FIG. 4A is a plan view illustrating an image sensor, according to an embodiment;

FIGS. 4B and 4C are sectional views taken along a line A-A′ of FIG. 4A, according to an embodiment;

FIG. 4D is a sectional view taken along a line B-B′ of FIG. 4A, according to an embodiment;

FIG. 5A is a plan view illustrating an image sensor, according to an embodiment;

FIGS. 5B and 5D are sectional views taken along a line A-A′ of FIG. 5A, according to an embodiment;

FIG. 5C is a sectional view taken along a line B-B′ of FIG. 5A, according to an embodiment;

FIG. 6A is a plan view illustrating an image sensor, according to an embodiment;

FIG. 6B is a sectional view taken along a line A-A′ of FIG. 6A, according to an embodiment;

FIGS. 7A, 8A, 9A, and 10A are sectional views, which are taken along the line A-A′ of FIG. 5A to illustrate a method of fabricating an image sensor, according to an embodiment; and

FIGS. 7B, 8B, 9B, and 10B are sectional views, which are taken along the line B-B′ of FIG. 5A to illustrate a method of fabricating an image sensor, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” “third” to be used to describe relative positions of elements. The terms “first,” “second,” “third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, and/or “enclosing” another element or layer, the element or layer may cover, overlap, and/or enclose at least a portion of the other element or layer, where the portion may include a fraction of the other element or may include an entirety of the other element. Similarly, when an element or layer is referred to as “penetrating”, “inserted in”, “extending” another element or layer, the element or layer may penetrate, insert, and/or extend into at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “SiGe”, “SiN”, “SiO”, “SiOC”, “SiON”, “TaN”, “TiN”, “WN”, “ZrN”, and the like may refer to a material made of elements included in each of the terms and is not a chemical formula representing a stoichiometric relationship.

Hereinafter, various embodiments of the present disclosure are described with reference to the accompanying drawings.

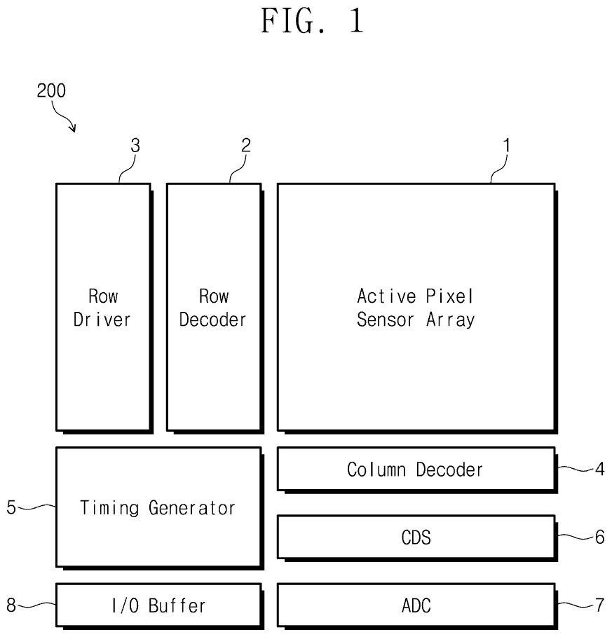

FIG. 1 is a block diagram illustrating an image sensor, according to an embodiment.

Referring to FIG. 1, the image sensor 200 may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of pixels, which may be and/or may include two-dimensionally (2D) arranged pixels that may be used to convert optical signals to electrical signals. The active pixel sensor array 1 may be driven by a plurality of driving signals (e.g., pixel selection signals, reset signals, charge transfer signals, or the like) provided by the row driver 3. In addition, the electrical signals, which may be converted by the active pixel sensor array 1, may be provided to the CDS 6.

The row driver 3 may provide a plurality of driving signals, which may be used to drive the plurality of pixels, to the active pixel sensor array 1, based on results decoded by the row decoder 2. When the pixels are arranged in a matrix shape, the driving signals may be applied to respective rows of the plurality of pixels.

The timing generator 5 may be configured to provide a timing signal and a control signal to the row decoder 2 and the column decoder 4.

The CDS 6 may be configured to receive the electric signals generated by the active pixel sensor array 1 and to perform a holding and sampling operation on the received electric signals. In addition, the CDS 6 may be configured to perform a double sampling operation on a specific noise level and a signal level of the electric signal and to output a difference level corresponding to a difference between the noise level and the signal level.

The ADC 7 may be configured to convert an analog signal, which may contain information on the difference level outputted by the CDS 6, to a digital signal and to output the converted digital signal.

The I/O buffer 8 may be configured to latch the digital signals and to sequentially output the latched digital signals to an image signal processing unit, based on the result decoded by the column decoder 4.

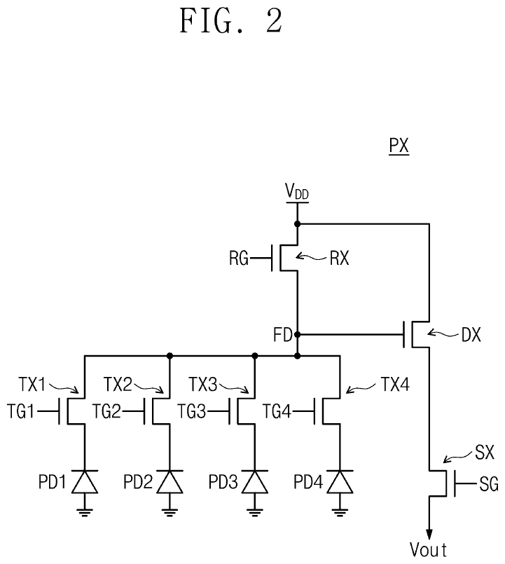

FIG. 2 is a circuit diagram illustrating a unit pixel of an image sensor, according to an embodiment.

Referring to FIGS. 1 and 2, the active pixel sensor array 1 may include a plurality of pixels PX, which may be arranged in a matrix shape. Each pixel of the plurality of pixels PX may include a first photoelectric conversion device PD1, a second photoelectric conversion device PD2, a third photoelectric conversion device PD3, a fourth photoelectric conversion device PD4, a first transfer transistor TX1, a second transfer transistor TX2, a third transfer transistor TX3, a fourth transfer transistor TX4, and logic transistors (e.g., a reset transistor RX, a selection transistor SX, and a drive transistor DX). The first transfer transistor TX1, the second transfer transistor TX2, the third transfer transistor TX3, the fourth transfer transistor TX4, the reset transistor RX, and the selection transistor SX may respectively include a first transfer gate electrode TG1, a second transfer gate electrode TG2, a third transfer gate electrode TG3, a fourth transfer gate electrode TG4, a reset gate RG, and a selection gate SG. Each pixel of the plurality of pixels PX may further include a floating diffusion region FD. Hereinafter, the first to fourth photoelectric conversion devices PD1 to PD4 may be respectively referred to as first to fourth photoelectric conversion regions PD1 to PD4.

The first to fourth photoelectric conversion devices PD1 to PD4 may be configured to generate photocharges in proportion to an amount of incident light and to store the photocharges therein. The first to fourth photoelectric conversion devices PD1 to PD4 may be and/or may include photodiodes, each of which may include a p-type impurity region and an n-type impurity region. The first transfer transistor TX1 may transfer electric charges, which may be generated in the first photoelectric conversion device PD1, to the floating diffusion region FD, and the second transfer transistor TX2 may transfer electric charges, which may generated in the second photoelectric conversion device PD2, to the floating diffusion region FD. The third transfer transistor TX3 may transfer electric charges, which may be generated in the third photoelectric conversion device PD3, to the floating diffusion region FD, and the fourth transfer transistor TX4 may transfer electric charges, which may be generated in the fourth photoelectric conversion device PD4, to the floating diffusion region FD.

The floating diffusion region FD may be configured to cumulatively store the electric charges, which may be generated in and transferred from the first to fourth photoelectric conversion devices PD1 to PD4. The drive transistor DX may be controlled based on an amount of the electric charges stored in the floating diffusion region FD.

The reset transistor RX may be configured to periodically discharge the photocharges from the floating diffusion region FD. A drain electrode of the reset transistor RX may be connected to the floating diffusion region FD, and a source electrode of the reset transistor RX may be connected to a power voltage VDD. When the reset transistor RX is turned on, the power voltage VDD, which may be connected to the source electrode of the reset transistor RX, may be applied to the floating diffusion region FD. Thus, when the reset transistor RX is turned on, the electric charges may be discharged from the floating diffusion region FD, and consequently, the floating diffusion region FD may be reset.

The drive transistor DX may serve as a source follower buffer amplifier. The drive transistor DX may be configured to amplify a variation in electric potential of the floating diffusion region FD and to output the amplified signal to an output line Vout.

The selection transistor SX may be used to select a row of the plurality of pixels PX to be read out during a read operation. When the selection transistor SX is turned on, the power voltage VDD may be applied to the drain electrode of the drive transistor DX.

Although FIG. 2 illustrates a unit pixel PX that includes four (4) photoelectric conversion devices (e.g., the first to fourth photoelectric conversion devices PD1 to PD4 and seven transistors (e.g., the first to fourth transfer transistors TX1 to TX4, the reset transistor RX, the selection transistor DX, and the drive transistor SX), the present disclosure is not limited in this regard. For example, the reset transistor RX, the drive transistor DX, and/or the selection transistor SX may be shared by adjacent ones of the pixels PX. In such an example, an integration density of the image sensor may be increased.

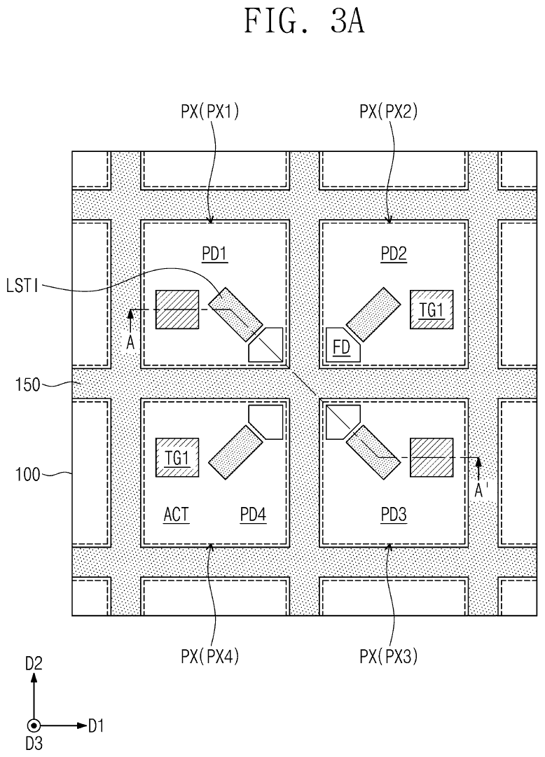

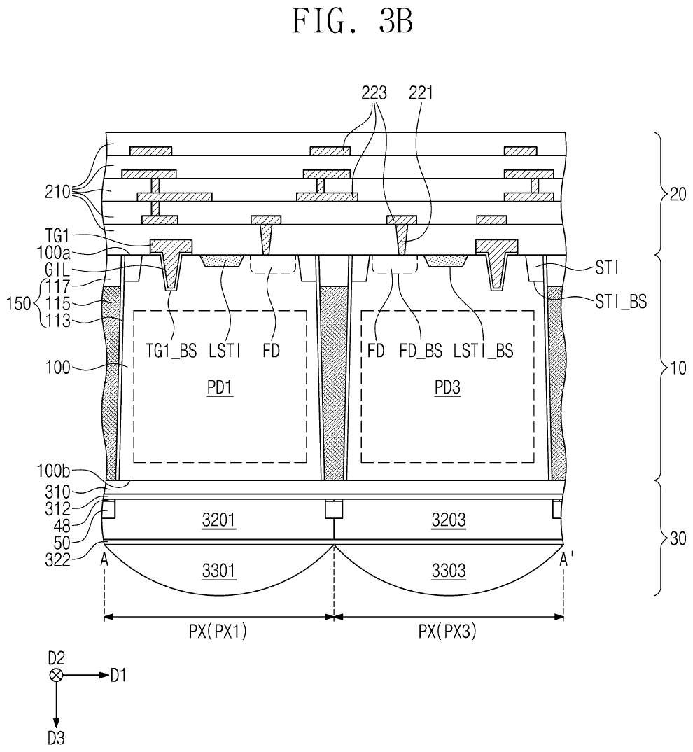

FIG. 3A is a plan view illustrating an image sensor, according to an embodiment. FIG. 3B is a sectional view taken along a line A-A′ of FIG. 3A to illustrate an image sensor, according to an embodiment.

Referring to FIGS. 3A and 3B, the image sensor may include a photoelectric conversion layer 10, an interconnection layer 20, and an optically-transparent layer 30. The photoelectric conversion layer 10 may be disposed between the interconnection layer 20 and the optically-transparent layer 30.

The photoelectric conversion layer 10 may include a substrate 100, and the substrate 100 may include a plurality of pixel regions PX. The substrate 100 may be and/or may include a semiconductor substrate (e.g., a silicon (Si) wafer, a germanium (Ge) wafer, a silicon-germanium (SiGe) wafer, a II-VI compound semiconductor wafer, or a III-V compound semiconductor wafer) or a silicon-on-insulator (SOI) wafer. The substrate 100 may have a first surface 100a and a second surface 100b, which may be opposite to each other. The pixel regions PX may be 2D arranged in a first direction D1 and a second direction D2, which may be parallel to the first surface 100a of the substrate 100. The first and second directions D1 and D2 may not be parallel to each other.

The photoelectric conversion layer 10 may further include a deep isolation pattern 150, which may be provided between the pixel regions PX to penetrate the substrate 100. The deep isolation pattern 150 may penetrate the substrate 100 in a third direction D3, which may be perpendicular to the first surface 100a of the substrate 100. The deep isolation pattern 150 may be extended from the first surface 100a of the substrate 100 toward the second surface 100b of the substrate 100. A top surface of the deep isolation pattern 150 may be substantially coplanar with the first surface 100a of the substrate 100, and a bottom surface of the deep isolation pattern 150 may be substantially coplanar with the second surface 100b of the substrate 100. The deep isolation pattern 150 may prevent a crosstalk issue from occurring between the pixel regions PX, which may be adjacent to each other.

The deep isolation pattern 150 may enclose each of the pixel regions PX, when viewed in a plan view. The deep isolation pattern 150 may define a plurality of pixel regions PX. The deep isolation pattern 150 may be extended in the first and second directions D1 and D2 to enclose each pixel region PX.

Photoelectric conversion regions PD may be respectively disposed in the pixel regions PX of the substrate 100.

In an embodiment, a first photoelectric conversion region PD1 may be disposed in a first pixel region PX1, and a second photoelectric conversion region PD2 may be disposed in a second pixel region PX2. The first and second pixel regions PX1 and PX2 may be adjacent to each other in the first direction D1. The first and second photoelectric conversion regions PD1 and PD2 may be adjacent to each other in the first direction D1. A third pixel region PX3 may be spaced apart from the second pixel region PX2 in the second direction D2. A fourth pixel region PX4 may be spaced apart from the third pixel region PX3 in the first direction D1. The third photoelectric conversion region PD3 may be disposed in the third pixel region PX3, and the fourth photoelectric conversion region PD4 may be disposed in the fourth pixel region PX4. The first to fourth photoelectric conversion regions PD1 to PD4 are illustrated to be arranged in a clockwise direction. However, the present disclosure is not limited in this regard. For example, the first to fourth photoelectric conversion regions PD1 to PD4 may be arranged in various other manners.

The deep isolation pattern 150 may be disposed between the first and second photoelectric conversion regions PD1 and PD2. The deep isolation pattern 150 between the first and second photoelectric conversion regions PD1 and PD2 may be extended in the second direction D2. This feature may also be applied to regions between the second and third photoelectric conversion regions PD2 and PD3 and between the third and fourth photoelectric conversion regions PD3 and PD4. The first to fourth photoelectric conversion regions PD1 to PD4 may convert light, which may be incident from the outside, to electrical signals.

A shallow isolation pattern STI may be disposed adjacent to the first surface 100a of the substrate 100. In each of the pixel regions PX, the shallow isolation pattern STI may define active portions ACT (or active patterns) in the substrate 100 and relatively near the first surface 100a. The shallow isolation pattern STI may be formed of and/or include at least one of, but not be limited to, silicon oxide (SiO), silicon nitride (SiN), or silicon oxynitride (SiON). In each of the pixel regions PX, the active portions ACT may be spaced apart from each other and may have different sizes from each other. The shallow isolation pattern STI may be interposed between the active patterns ACT.

The deep isolation pattern 150 may include a liner insulating pattern 113, a semiconductor pattern 115, and a capping insulating pattern 117. The semiconductor pattern 115 may penetrate at least a portion of the substrate 100 in the third direction D3. The liner insulating pattern 113 may be provided between the semiconductor pattern 115 and the substrate 100. The capping insulating pattern 117 may be provided on the semiconductor pattern 115.

A bottom surface of the semiconductor pattern 115 may be located at a substantially similar level and/or the same level as the second surface 100b of the substrate 100. A top surface of the semiconductor pattern 115 may be in direct contact with a bottom surface of the capping insulating pattern 117. In an embodiment, an air gap and/or a void may be formed in the semiconductor pattern 115. The semiconductor pattern 115 may be formed of and/or may include, for example, polysilicon, or the like. The semiconductor pattern 115 may be formed of and/or may include, but not be limited to, a doped semiconductor material. The semiconductor pattern 115 may be formed of and/or may include, but not be limited to, a semiconductor material of p-type and/or n-type. For example, the semiconductor pattern 115 may be formed of and/or may include boron-doped polysilicon.

The substrate 100 may have a first conductivity type, and the first and second photoelectric conversion regions PD1 and PD2 may be doped to have a second conductivity type different from the first conductivity type. In an embodiment, the first conductivity type and the second conductivity type may be a p-type and an n-type, respectively. In such an embodiment, the impurity of the second conductivity type may contain n-type impurities (e.g., phosphorus (P), arsenic (As), bismuth (Bi), and/or antimony (Sb)). Each of the first and second photoelectric conversion regions PD1 and PD2 and the substrate 100 may form a PN junction serving as a photodiode. In an embodiment, the semiconductor pattern 115 of the deep isolation pattern 150 may be formed of and/or may include a semiconductor material that may be doped with the impurity of the first conductivity type (e.g., the p-type impurity).

The bottom surface of the capping insulating pattern 117 may be located at a level that may be lower than or equal to a bottom surface of the shallow isolation pattern STI. The bottom surface of the capping insulating pattern 117 may have a rounded shape. A top surface of the capping insulating pattern 117 may be located at a substantially similar and/or the same level as a top surface of the shallow isolation pattern STI (e.g., the first surface 100a of the substrate 100).

The liner insulating pattern 113 may be provided to cover a side surface of the semiconductor pattern 115 and a side surface of the capping insulating pattern 117 conformally (e.g., with a substantially constant thickness). In an embodiment, the liner insulating pattern 113 and the capping insulating pattern 117 may be formed of and/or may include at least one of silicon oxide (SiO), silicon oxynitride (SiON), or silicon nitride (SiN).

The first transfer gate electrode TG1 and the floating diffusion region FD may be disposed on each pixel region PX and relatively near the first surface 100a of the substrate 100. The first transfer gate electrode TG1 and the floating diffusion region FD may be disposed on a corresponding one of the active portions ACT. The first transfer gate electrode TG1 may be overlapped with the first photoelectric conversion region PD1 vertically (e.g., in the third direction D3). This feature may also be applied to the second to fourth photoelectric conversion regions PD2 to PD4. The first transfer gate electrode TG1 may be extended from the first surface 100a of the substrate 100 into the substrate 100. The position of the first transfer gate electrode TG1 may not be limited to the illustrated example.

The first transfer gate electrode TG1 may include a portion that may be provided in the active portion ACT of the first pixel region PX1. For example, the first transfer gate electrode TG1 may be extended into the substrate 100. At least a portion of the first transfer gate electrode TG1 may be provided in a vertical trench, which may be recessed from the first surface 100a of the substrate 100. The first transfer gate electrode TG1 may include a lower portion, which may be inserted into the substrate 100, and an upper portion, which may be extended from the lower portion to a level higher than the first surface 100a of the substrate 100.

The lower portion of the first transfer gate electrode TG1 may penetrate at least a portion of the substrate 100. The lower portion of each of the first transfer gate electrodes TG1 may be extended into the substrate 100 toward the first photoelectric conversion region PD1, and the upper portion of each of the first transfer gate electrodes TG1 may be a protruding portion that may be placed at a level higher than a top surface of a corresponding one of the active patterns ACT (e.g., the first surface 100a of the substrate 100).

A bottom surface of the first transfer gate electrode TG1 may be placed at a level lower than the first surface 100a of the substrate 100. For example, a bottom surface TG1_BS of the first transfer gate electrode TG1 may be located at a level lower than a bottom surface STI_BS of the shallow isolation pattern STI. That is, the bottom surface STI_BS of the shallow isolation pattern STI may be closer to the first surface 100a of the substrate 100 than the bottom surface TG1_BS of the first transfer gate electrode TG1. A gate insulating layer GIL may be interposed between the first transfer gate electrode TG1 and the substrate 100.

The photoelectric conversion layer 10 may further include the floating diffusion regions FD, which may be disposed in the pixel region PX of the substrate 100 and may be overlapped with the first to fourth photoelectric conversion regions PD1 to PD4, respectively. Each of the floating diffusion regions FD may be overlapped with a corresponding one of the first to fourth photoelectric conversion regions PD1 to PD4. In an embodiment, one photoelectric conversion region may be overlapped with one floating diffusion region FD.

The floating diffusion regions FD may be spaced apart from each other in the first direction D1, with the deep isolation pattern 150 interposed therebetween. The first transfer gate electrodes TG1 may be disposed to be adjacent to the floating diffusion region FD. The floating diffusion region FD may be spaced apart from the first transfer gate electrode TG1. The floating diffusion region FD may be doped with impurities, which may be of the second conductivity type (e.g., n-type) different from the first conductivity type of the substrate 100.

The substrate 100 of the first conductivity type and each of the first to fourth photoelectric conversion regions PD1 to PD4 of the second conductivity type may form a junction serving as a photodiode. Light, which may be incident through the second surface 100b of the substrate 100, may generate electric charges in the first to fourth photoelectric conversion regions PD1 to PD4.

The photoelectric conversion layer 10 may further include a barrier device isolation pattern LSTI, which may be disposed in the pixel region PX of the substrate 100 and may be spaced apart from the floating diffusion region FD.

The barrier device isolation pattern LSTI may be extended from the first surface 100a of the substrate 100 into the substrate 100. The barrier device isolation pattern LSTI may be disposed between the floating diffusion region FD and the first transfer gate electrode TG1. The barrier device isolation pattern LSTI may be spaced apart from the first transfer gate electrode TG1. A level of a bottom surface LSTI_BS of the barrier device isolation pattern LSTI may be higher than a level of a bottom surface FD_BS of the floating diffusion region FD. The level of the bottom surface LSTI_BS of the barrier device isolation pattern LSTI may be higher than a level of the bottom surface TG1_BS of the first transfer gate electrode TG1. The level of the bottom surface LSTI_BS of the barrier device isolation pattern LSTI may be different from a level of the bottom surface STI_BS of the shallow isolation pattern STI. The level of the bottom surface LSTI_BS of the barrier device isolation pattern LSTI may be higher than the level of the bottom surface STI_BS of the shallow isolation pattern STI. The barrier device isolation pattern LSTI and the shallow isolation pattern STI may include different materials from each other.

When the barrier device isolation pattern LSTI is disposed between the floating diffusion region FD and the first transfer gate electrode TG1, a facing area between the floating diffusion region FD and the first transfer gate electrode TG1 may be reduced. In such an embodiment, it may be possible to reduce a noise signal in each pixel.

The interconnection layer 20 may include interconnection lines (e.g., metal-oxide-semiconductor (MOS) transistors), which may be connected to the photoelectric conversion layer 10. Electrical signals, which may be converted by the photoelectric conversion layer 10, may be processed in the interconnection layer 20.

The interconnection layer 20 may be disposed on the first surface 100a of the substrate 100. The interconnection layer 20 may include interlayer insulating layers 210, which may be sequentially stacked on the first surface 100a of the substrate 100. The interlayer insulating layer 210 may be disposed on the first surface 100a of the substrate 100 to cover the first transfer gate electrode TG1. The interlayer insulating layers 210 may include an insulating material. The interlayer insulating layers 210 may be formed of and/or may include at least one of, but not be limited to, silicon oxide (SiO), silicon oxynitride (SiON), or silicon nitride (SiN).

The interconnection layer 20 may further include interconnection structures (e.g., a first interconnection structure 221 and a second interconnection structure 223), which may be provided in the interlayer insulating layer 210. The first and second interconnection structures 221 and 223 may include metal lines 223 and contact plugs 221, which may be provided to connect the metal lines 223 to each other. At least one of the contact plugs 221 may be coupled to the floating diffusion region FD. The metal lines 223 and the contact plugs 221 may include a conductive material.

The optically-transparent layer 30 may be provided on the second surface 100b of the substrate 100. The optically-transparent layer 30 may include a planarization insulating layer 310, a protection layer 312, light-blocking patterns 48, low-refractive patterns 50, color filters (e.g., a first color filter 3201 and a second color filter 3203), and micro lenses (e.g., a first micro lens 3301 and a second micro lens 3303).

The planarization insulating layer 310 may be interposed between the second surface 100b of the substrate 100 and the first and second color filters 3201 and 3203. The planarization insulating layer 310 may include a plurality of insulating layers, which may have different refractive indices from each other, and each of the insulating layers may include a transparent insulating material. Thicknesses of the insulating layers may be variously adjusted to realize high transmittance of the planarization insulating layer 310. In an embodiment, the planarization insulating layer 310 may be and/or may include a metal oxide layer whose oxygen content is lower than its stoichiometric ratio, a metal fluoride layer whose fluorine content ratio is lower than its stoichiometric ratio, or a single or multi-layered structure including at least one of the metal oxide layer or the metal fluoride layer. In such an embodiment, the planarization insulating layer 310 may have negative fixed charges and may be used as a fixed charge layer. For example, the planarization insulating layer 310 may include a metal oxide layer and/or a metal fluoride layer, which may contain at least one of, but not be limited to, hafnium (Hf), zirconium (Zr), aluminum (Al), tantalum (Ta), titanium (Ti), yttrium (Y), or lanthanum (La). The planarization insulating layer 310 may be used to suppress a dark current issue and a white spot issue.

The protection layer 312 may be stacked on the planarization insulating layer 310. The protection layer 312 may be formed of and/or may include at least one of, but not be limited to, silicon oxide (SiO), silicon carbon oxide (SiOC), or silicon nitride (SiN).

The light-blocking patterns 48 may be disposed on the protection layer 312. The low-refractive patterns 50 may be disposed on the light-blocking patterns 48, respectively. When viewed in a plan view, the light-blocking pattern 48 and the low-refractive pattern 50 may be overlapped with the deep isolation pattern 150 and may have a grid shape. The light-blocking pattern 48 may be formed of and/or may include, for example, titanium (Ti), or the like. The low-refractive patterns 50 may have a substantially similar and/or the same thickness and may be formed of and/or may include the same organic material. The low-refractive pattern 50 may have a refractive index that may be lower than the refractive index of the first and second color filters 3201 and 3203. For example, the low-refractive pattern 50 may have a refractive index of about 1.3 or lower. The light-blocking pattern 48 and the low-refractive pattern 50 may prevent a crosstalk issue from occurring between the pixels PX, which may be adjacent to each other.

Color filters may be provided to correspond to the first to fourth pixel regions PX1 to PX4, respectively. In an embodiment, the first color filter 3201 corresponding to the first pixel region PX1 may be provided in the first pixel region PX1. This feature may also be applied to the second to fourth pixel regions PX2 to PX4.

The first and second color filters 3201 and 3203 may be disposed between the low-refractive patterns 50. Each of the first and second color filters 3201 and 3203 may have one of blue, green, and red colors. In an embodiment, the first and second color filters 3201 and 3203 may be provided to have other colors, such as cyan, magenta, or yellow. In the image sensor, according to an embodiment, the first and second color filters 3201 and 3203 may be arranged in the form of a Bayer pattern. Alternatively, the first and second color filters 3201 and 3203 may be arranged in the form of a 2×2 tetra pattern, a 3×3 nona pattern, or a 4×4 hexadeca pattern.

A lens insulating layer 322 may be interposed between the first and second color filters 3201 and 3203 and the first and second micro lenses 3301 and 3303. The first and second micro lenses 3301 and 3303 may be disposed on the lens insulating layer 322. The first and second micro lenses 3301 and 3303 may be overlapped with corresponding first and third photoelectric conversion regions PD1 and PD3. In an embodiment, a first micro lens 3301 may be overlapped with the first photoelectric conversion region PD1.

The sectional view of FIG. 3B illustrates the first and third photoelectric conversion regions PD1 and PD3, which are provided in the first and third pixel regions PX1 and PX3, respectively, but the technical features described above or to be described below may be applied to the second and fourth photoelectric conversion regions PD2 and PD4 in the same manner.

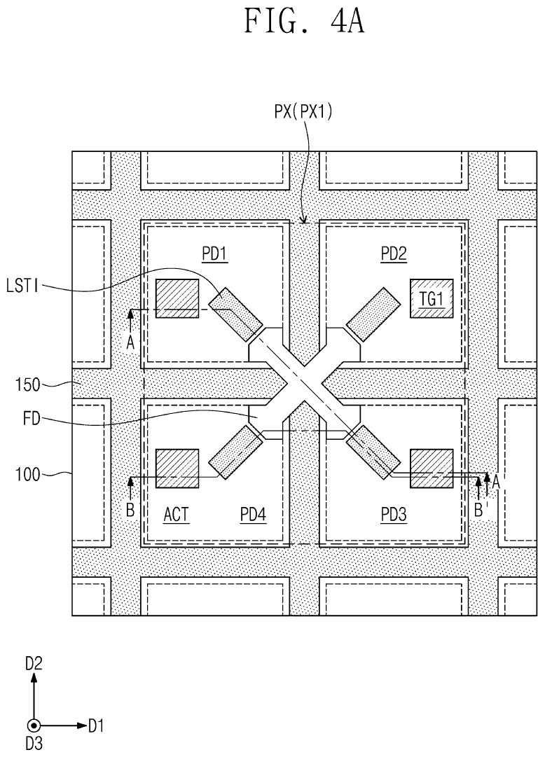

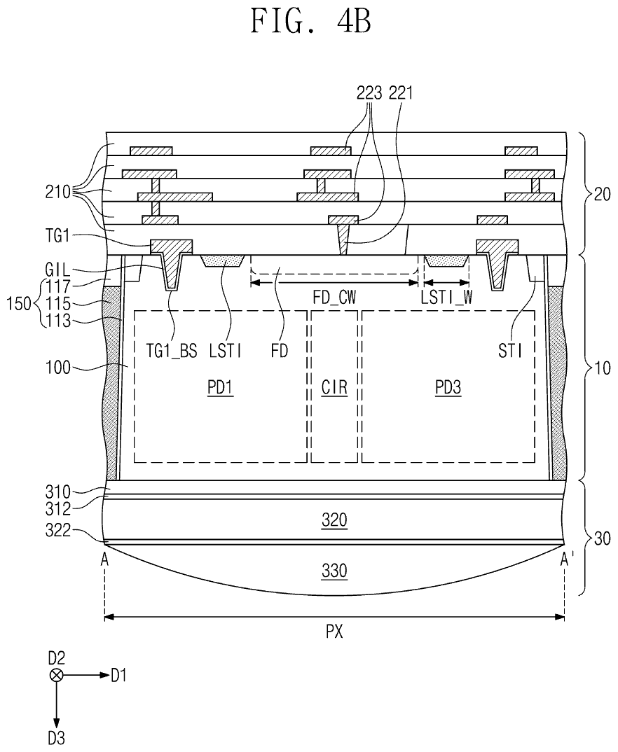

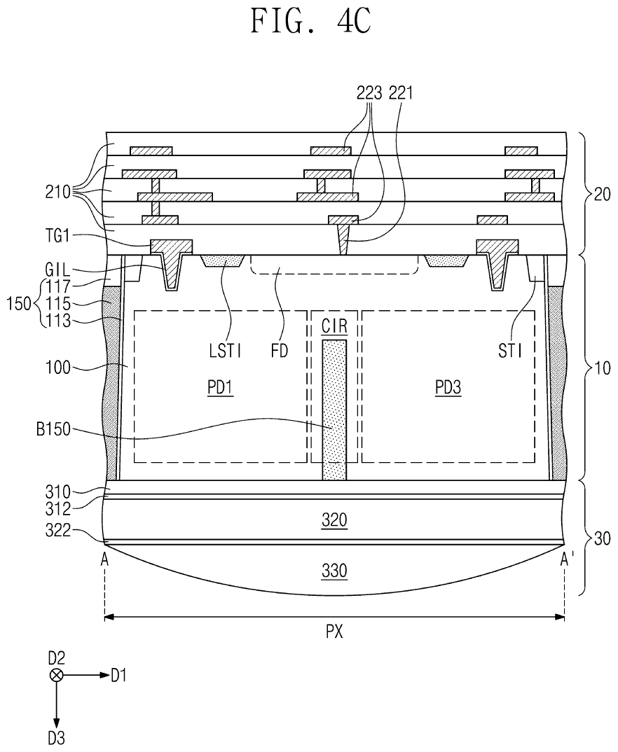

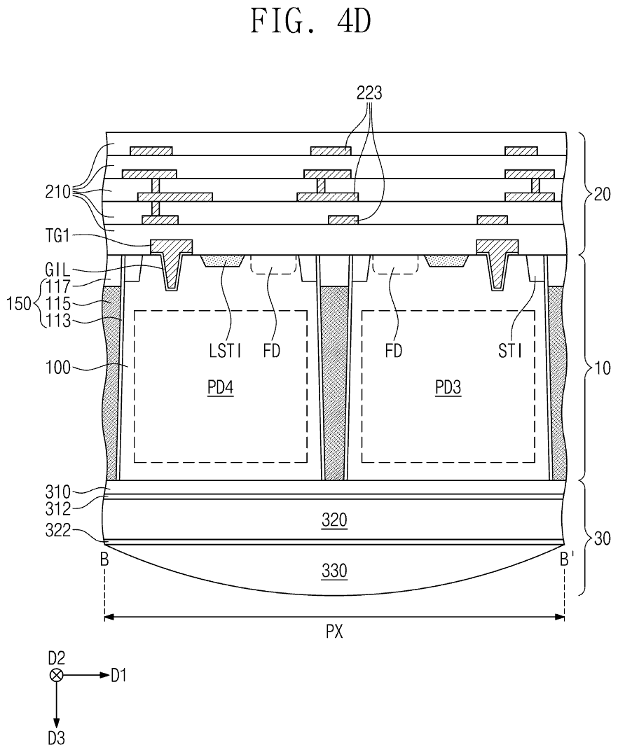

FIG. 4A is a plan view illustrating an image sensor, according to an embodiment. FIGS. 4B and 4C are sectional views taken along a line A-A′ of FIG. 4A, according to an embodiment. FIG. 4D is a sectional view taken along a line B-B′ of FIG. 4A, according to an embodiment. The same elements as in the image sensor described with reference to FIGS. 3A and 3B may be identified by the same reference numbers in FIGS. 4A to 4D. Consequently, repeated descriptions of the elements described above with reference to FIGS. 3A and 3B may be omitted for the sake of brevity.

Referring to FIGS. 4A, 4B, and 4D, one micro lens 330 may be provided to correspond to the first to fourth photoelectric conversion regions PD1 to PD4. In an embodiment, one micro lens 330 may be commonly provided on the first to fourth photoelectric conversion regions PD1 to PD4. The first to fourth photoelectric conversion regions PD1 to PD4 may define one pixel region PX. A color filter 320 may be provided to correspond to the first to fourth photoelectric conversion regions PD1 to PD4.

Each floating diffusion region FD may be provided to correspond to the first to fourth photoelectric conversion regions PD1 to PD4. For example, the floating diffusion region FD may be provided to be overlapped with the first to fourth photoelectric conversion regions PD1 to PD4.

The deep isolation pattern 150 may be extended into a region of the substrate, which may be placed between the first and second photoelectric conversion regions PD1 and PD2 but may not be overlapped with the floating diffusion region FD. The deep isolation pattern 150 may also be extended into regions between the second and third photoelectric conversion regions PD2 and PD3, between the third and fourth photoelectric conversion regions PD3 and PD4, and between the fourth and first photoelectric conversion regions PD4 and PD1.

The deep isolation pattern 150 may not be extended into a region of the substrate, which may be overlapped with the floating diffusion region FD between the first and third photoelectric conversion regions PD1 and PD3. Similarly, the deep isolation pattern 150 may not be extended into a region, which may be overlapped with the floating diffusion region FD between the second and fourth photoelectric conversion regions PD2 and PD4.

A central intervening region CIR may be defined in the region of the substrate, which may be overlapped with the floating diffusion region FD between the first and third photoelectric conversion regions PD1 and PD3. The floating diffusion region FD may be overlapped with the central intervening region CIR. The central intervening region CIR may contain dopants that may be different from those in the first and third photoelectric conversion regions PD1 and PD3. In an embodiment, the central intervening region CIR may be a deep trench isolation (DTI) center cut (DCC) region.

The barrier device isolation pattern LSTI may be provided between the floating diffusion region FD and a transfer gate electrode TG. The largest width FD_CW of the floating diffusion region FD may be larger than a width LSTI_W of the barrier device isolation pattern LSTI. The largest width FD_CW of the floating diffusion region FD may be defined as the largest distance between two opposite ends of the floating diffusion region FD, which may be respectively overlapped with a pair of the photoelectric conversion regions PD1 that may be adjacent to each other. The width LSTI_W may be defined as a width of the barrier device isolation pattern LSTI that is in contact with the first surface 100a of the substrate 100.

Referring to FIGS. 4A and 4C, an isolation structure B150 may be additionally provided in the substrate 100 overlapped with the floating diffusion region FD. In such an embodiment, the isolation structure B150 may be provided in the central intervening region CIR. The isolation structure B150 may be additionally disposed between the first and third photoelectric conversion regions PD1 and PD3. The isolation structure B150 may be additionally disposed between the second and fourth photoelectric conversion regions PD2 and PD4. The isolation structure B150 may be extended from the second surface 100b of the substrate 100 into the substrate 100. The isolation structure B150 may include an insulating material.

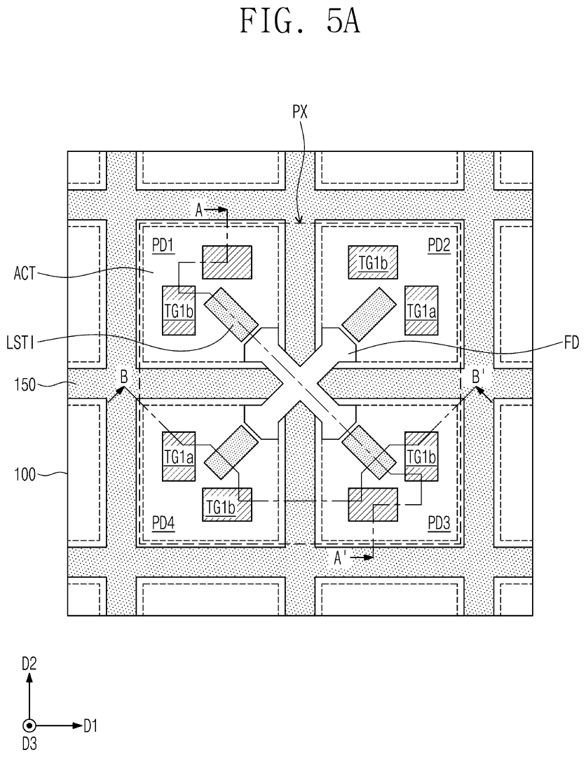

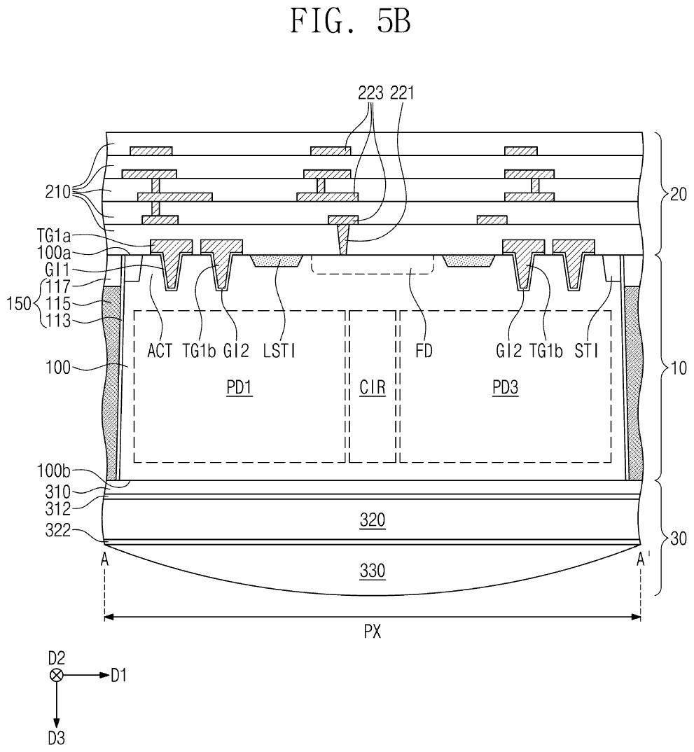

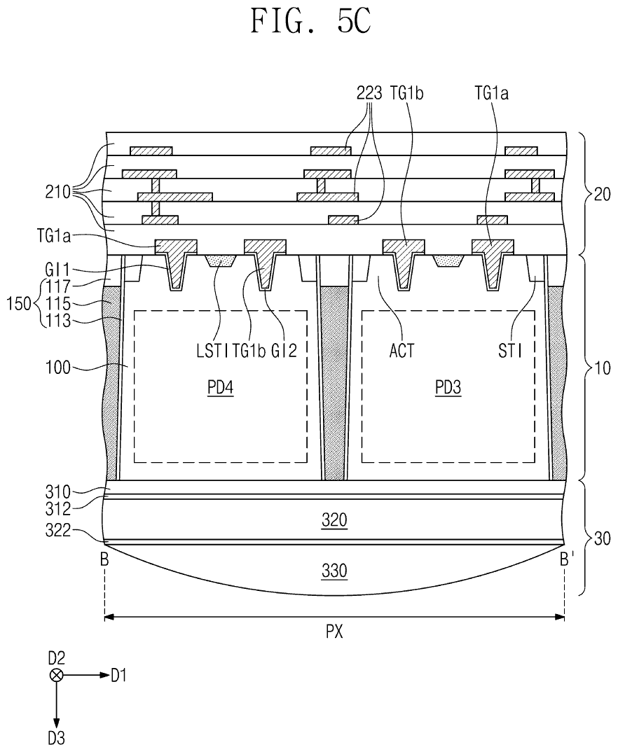

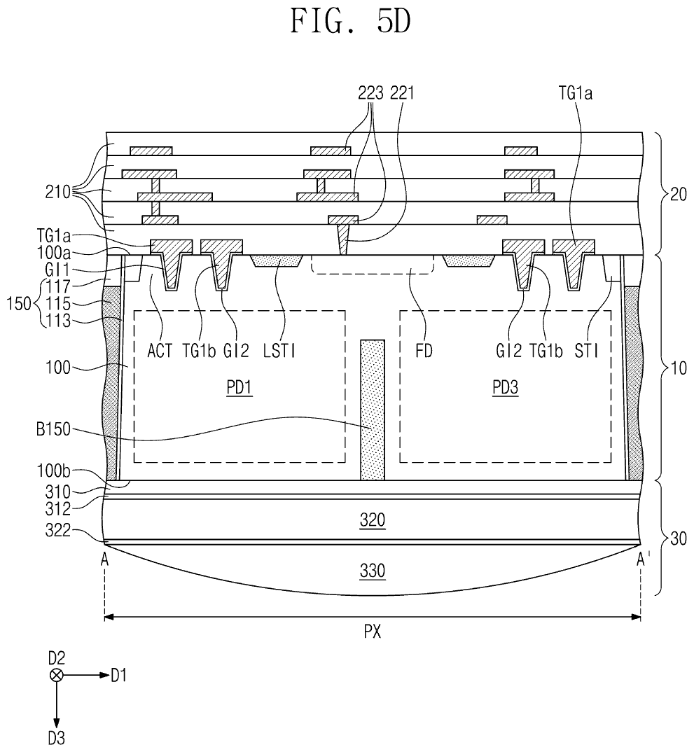

FIG. 5A is a plan view illustrating an image sensor, according to an embodiment. FIGS. 5B and 5D are sectional views taken along a line A-A′ of FIG. 5A, according to an embodiment. FIG. 5C is a sectional view taken along a line B-B′ of FIG. 5A, according to an embodiment. The same elements as in the image sensor described with reference to FIGS. 4A to 4D may be identified by the same reference numbers in FIGS. 5A to 5D. Consequently, repeated descriptions of the elements described above with reference to FIGS. 4A to 4D may be omitted for the sake of brevity.

Referring to FIGS. 5A, 5B, and 5C, a plurality of transfer gate electrodes (e.g., a first transfer gate electrode TG1a and a second transfer gate electrode TG1b) may be provided to correspond to one photoelectric conversion region. In an embodiment, the first and second transfer gate electrodes TG1a and TG1b, which may be spaced apart from each other, may be provided to correspond to the first photoelectric conversion region PD1. The first and second transfer gate electrodes TG1a and TG1b may be overlapped with the first photoelectric conversion region PD1. The first and second transfer gate electrodes TG1a and TG1b may be overlapped with one of the micro lenses 330. The first photoelectric conversion region PD1 may be overlapped with the barrier device isolation pattern LSTI, the first transfer gate electrode TG1a, the second transfer gate electrode TG1b, and the floating diffusion region FD.

Referring back to FIG. 5B, a lower portion of each of the first and second transfer gate electrodes TG1a and TG1b may be extended into the substrate 100 and/or toward a first photoelectric conversion region 110a, and an upper portion of each of the first and second transfer gate electrodes TG1a and TG1b may be a protruding portion that may be placed on a top surface of a corresponding one of the active patterns ACT (e.g., the first surface 100a of the substrate 100). The upper portions of the first and the second transfer gate electrodes TG1a and TG1b may be spaced apart from each other.

In an embodiment, upper portions of adjacent ones of the first and the second transfer gate electrodes TG1a and TG1b may be connected to each other.

The barrier device isolation pattern LSTI may be disposed between the first and second transfer gate electrodes TG1a and TG1b and the floating diffusion region FD. In such an embodiment, a facing area between the floating diffusion region FD and the first and the second transfer gate electrodes TG1a and TG1b may be reduced, and as such, may provide for a potential noise reduction of the image sensor, when compared to related image sensors.

Referring to FIGS. 5A and 5D, the isolation structure B150 may be additionally provided in the substrate 100 overlapped with the floating diffusion region FD, similar to the embodiment of FIG. 4C. The isolation structure B150 may be additionally disposed between the first and third photoelectric conversion regions PD1 and PD3. The isolation structure B150 may be additionally disposed between the second and fourth photoelectric conversion regions PD2 and PD4.

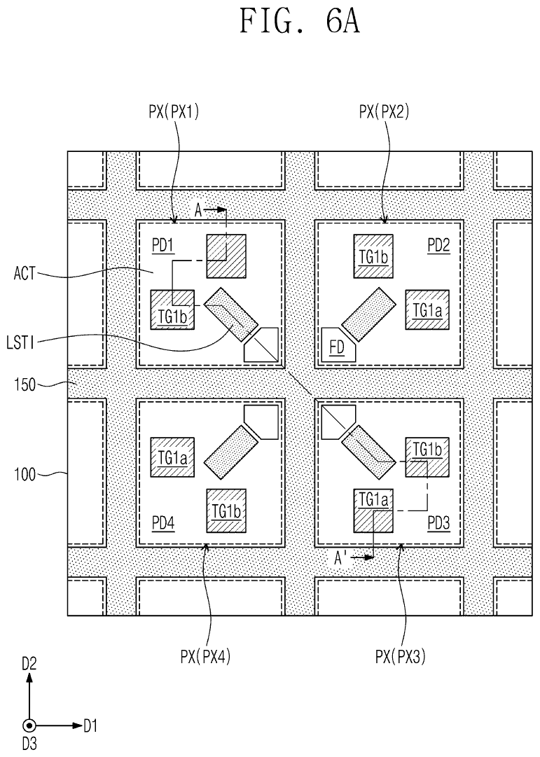

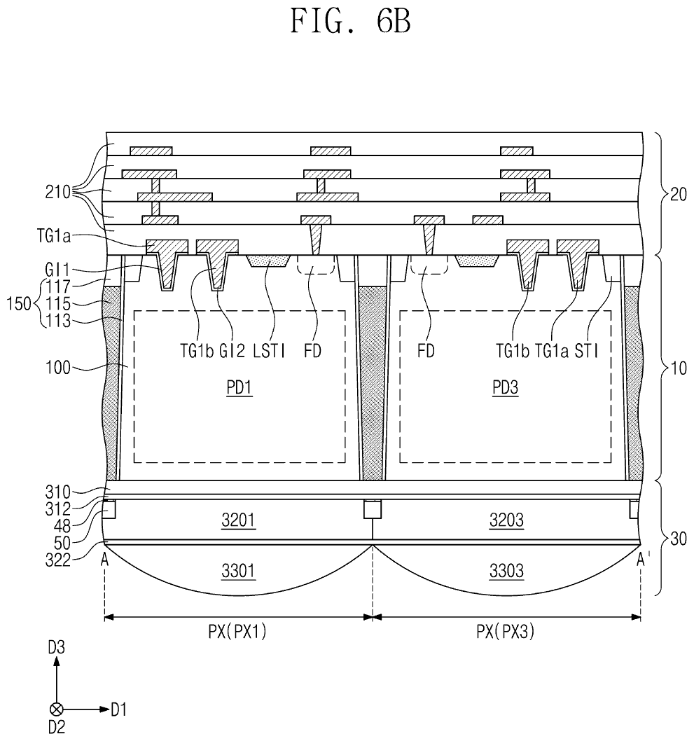

FIG. 6A is a plan view illustrating an image sensor, according to an embodiment. FIG. 6B is a sectional view taken along a line A-A′ of FIG. 6A, according to an embodiment. The same elements as in the image sensor described with reference to FIGS. 3A and 3B may be identified by the same reference numbers in FIGS. 6A and 6B. Consequently, repeated descriptions of the elements described above with reference to FIGS. 3A and 3B may be omitted for the sake of brevity.

Referring to FIGS. 6A and 6B, the first and second transfer gate electrodes TG1a and TG1b may be provided to correspond to one photoelectric conversion region. In an embodiment, the first photoelectric conversion region PD1 may be overlapped with the first transfer gate electrode TG1a, the second transfer gate electrode TG1b, the barrier device isolation pattern LSTI, and the floating diffusion region FD.

Each of the first to fourth photoelectric conversion regions PD1 to PD4 may be overlapped with a corresponding one of the barrier device isolation patterns LSTI and a corresponding one of the floating diffusion regions FD. The deep isolation pattern 150 may be provided to enclose the first photoelectric conversion region PD1. This feature may also be applied to the second to fourth photoelectric conversion regions PD2 to PD4.

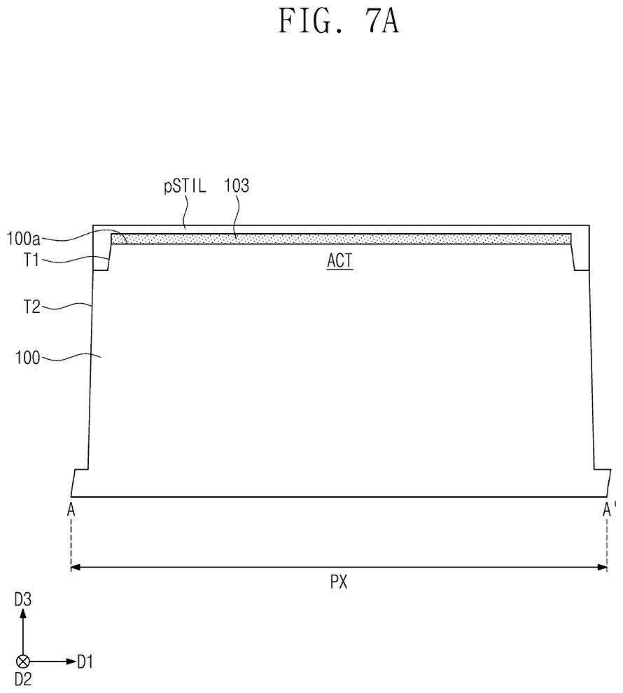

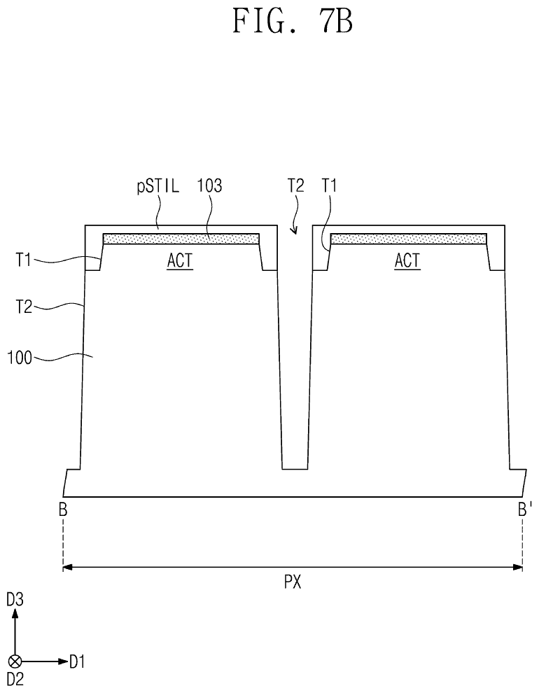

FIGS. 7A, 8A, 9A, and 10A are sectional views, which are taken along the line A-A′ of FIG. 5A to illustrate a method of fabricating an image sensor, according to an embodiment. FIGS. 7B, 8B, 9B, and 10B are sectional views, which are taken along the line B-B′ of FIG. 5A to illustrate a method of fabricating an image sensor, according to an embodiment.

Referring to FIG. 7A, the substrate 100 may be provided to include the first and second surfaces 100a and 100b, which are opposite to each other. The substrate 100 may have a first conductivity type (e.g., p-type). A first trench T1 may be formed relatively near the first surface 100a of the substrate 100. The formation of the first trench T1 may include forming a first mask pattern 103 on the first surface 100a of the substrate 100 and etching the substrate 100 using the first mask pattern 103 as an etch mask. The first trench T1 may define the active portion ACT in the substrate 100.

A device isolation layer pSTIL may be formed on the first surface 100a of the substrate 100. The device isolation layer pSTIL may cover the first mask pattern 103 and may fill the first trench T1. In an embodiment, the device isolation layer pSTIL may include, but not be limited to, a silicon oxide (SiO) layer, a silicon nitride (SiN) layer, and/or a silicon oxynitride (SiON) layer.

A second trench T2 may be formed in the substrate 100. The formation of the second trench T2 may include forming a second mask pattern on the device isolation layer pSTIL to define a region for the second trench T2 and etching the device isolation layer pSTIL and the substrate 100 using the second mask pattern as an etch mask.

The second trench T2 may define a plurality of pixel regions PX in the substrate 100. The pixel regions PX may be arranged in the first and second directions D1 and D2. The second trench T2 may enclose each pixel region PX, when viewed in a plan view. The second trench T2 may be extended in the first and second directions D1 and D2 to enclose each pixel region PX. Each of the pixel regions PX may include the active portions ACT, which may be defined by the first trench T1. Referring to FIG. 7B, the second trench T2 may be extended into the pixel region PX.

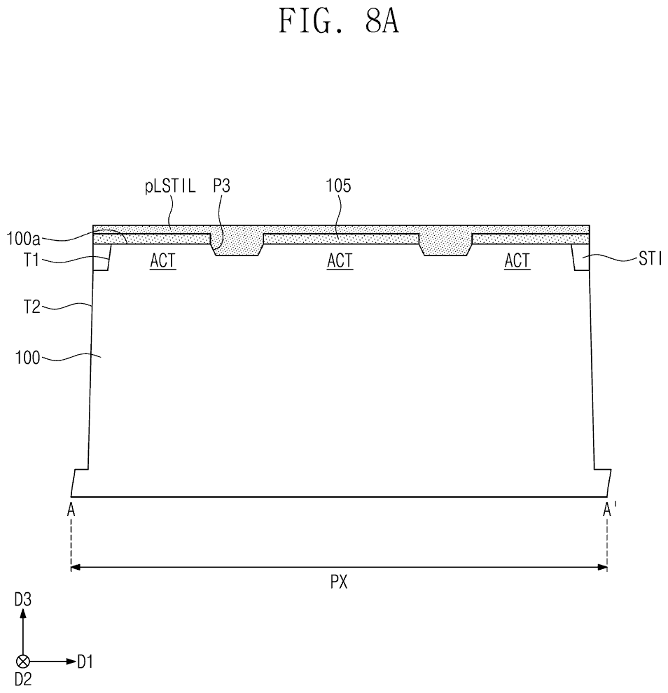

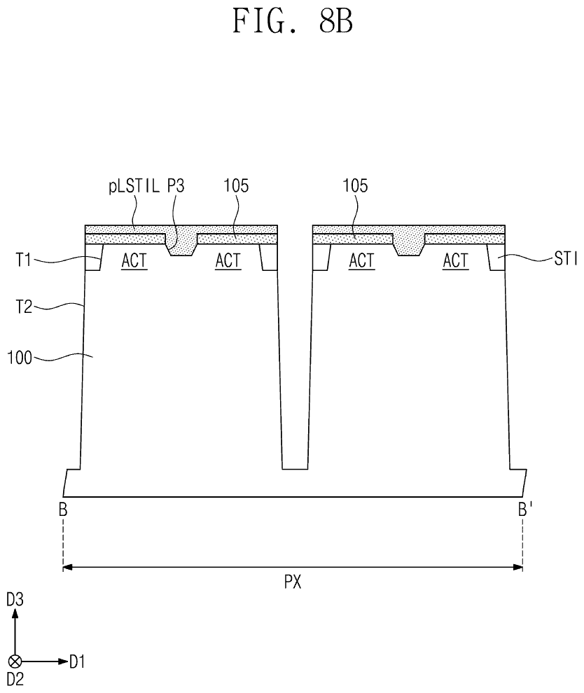

Referring to FIGS. 8A and 8B, the shallow isolation pattern STI, a third mask pattern 105 on the shallow isolation pattern STI, a preliminary barrier layer pLSTIL on the third mask pattern 105 may be formed.

An upper portion of the device isolation layer pSTIL and the first mask pattern 103 may be removed to form the shallow isolation pattern STI. A portion of the device isolation layer pSTIL, which may be located at a level lower than the first surface 100a of the substrate 100, may remain, and the other portion of the device isolation layer pSTIL may be removed.

The third mask pattern 105 may be formed on the top surface of the shallow isolation pattern STI and the top surface of the substrate 100, which may be exposed by removing the upper portion of the device isolation layer pSTIL and the first mask pattern 103. A third trench P3 may be formed by a patterning process using the third mask pattern 105.

The formation of the third trench P3 may include forming the third mask pattern 105 on the exposed top surface of the shallow isolation pattern STI and the exposed top surface of the substrate 100 to define a region for the third trench P3 and etching the substrate 100 using the third mask pattern 105 as an etch mask.

The preliminary barrier layer pLSTIL may be formed to cover the third mask pattern 105 and fill the third trench P3. In an embodiment, the preliminary barrier layer pLSTIL may include a material different from the device isolation layer pSTIL. In an embodiment, the preliminary barrier layer pLSTIL may be formed of and/or may include the same material as the device isolation layer pSTIL. The second trench T2 may not be filled with the preliminary barrier layer pLSTIL and may be exposed to the outside.

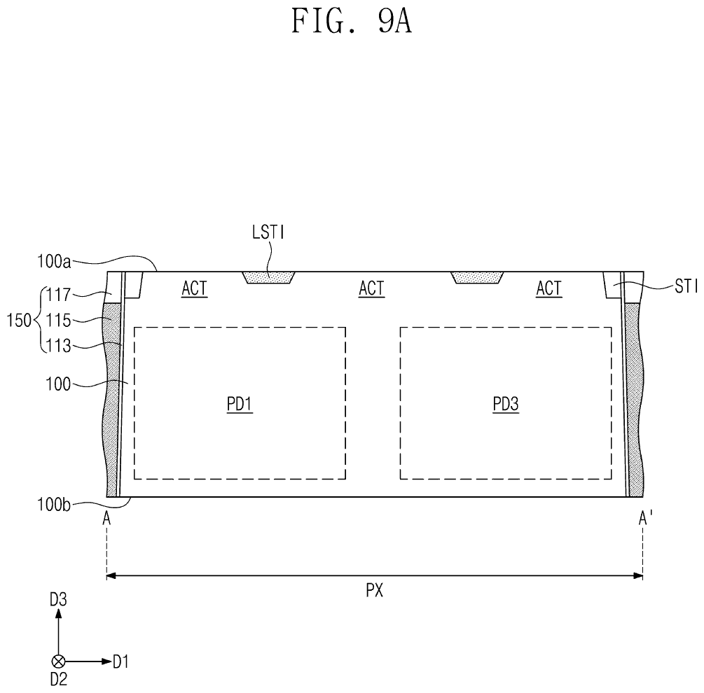

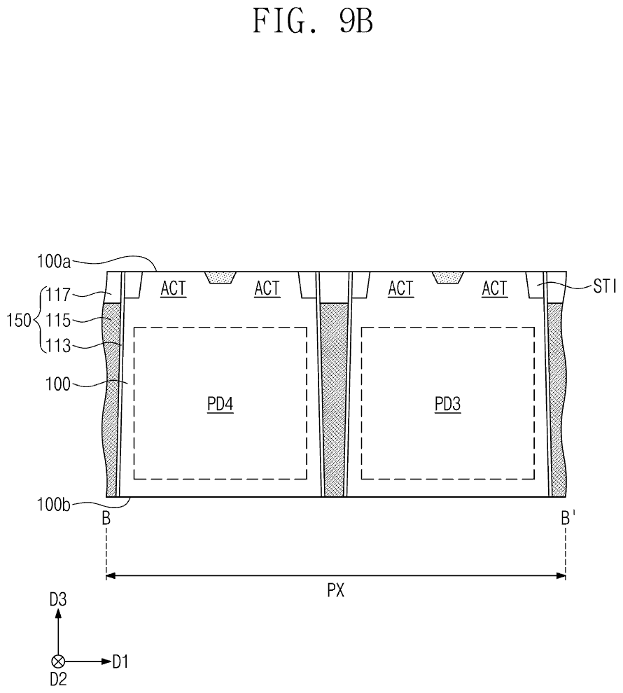

Referring to FIGS. 9A and 9B, the barrier device isolation pattern LSTI may be formed by removing an upper portion of the preliminary barrier layer pLSTIL and the third mask pattern 105. For example, a portion of the preliminary barrier layer pLSTIL, which may be located at a level higher than the first surface 100a of the substrate 100, may be removed.

The deep isolation pattern 150 may be formed to fill the second trench T2. The deep isolation pattern 150 may include the liner insulating pattern 113 conformally filling an inner surface of the second trench T2, the semiconductor pattern 115 filling a lower portion of the second trench T2, and the capping insulating pattern 117 provided on the semiconductor pattern 115 to fill a remaining portion of the second trench T2.

In an embodiment, the formation of the deep isolation pattern 150 may include forming a liner insulating layer on the preliminary barrier layer pLSTIL to conformally cover an inner surface of the second trench T2, forming a semiconductor layer on the liner insulating layer to fill the second trench T2, etching the semiconductor layer in an etch-back manner to form the semiconductor pattern 115, forming a capping insulating layer to fill a remaining portion of the second trench T2, and planarizing the capping insulating layer and the liner insulating layer to form the liner insulating pattern 113 and the capping insulating pattern 117.

In an embodiment, the formation of the semiconductor pattern 115 may further include injecting impurities of a first conductivity type (e.g., p-type) into the semiconductor pattern 115. The planarization process, which may be performed to form the liner insulating pattern 113 and the capping insulating pattern 117, may include planarizing the capping insulating layer, the liner insulating layer, and the preliminary barrier layer pLSTIL until the first surface 100a of the substrate 100 is exposed to the outside.

The first and second photoelectric conversion regions PD1 and PD2 may be formed in the pixel region PX. Similarly, the third and fourth photoelectric conversion regions PD3 and PD4 may be formed in the pixel region PX.

The deep isolation pattern 150 may be interposed between the first and second photoelectric conversion regions PD1 and PD2. The deep isolation pattern 150 may be interposed between the second and third photoelectric conversion regions PD2 and PD3 and between the third and fourth photoelectric conversion regions PD3 and PD4. The deep isolation pattern 150 may not be interposed between the first and third photoelectric conversion regions PD1 and PD3 and between the second and fourth photoelectric conversion regions PD2 and PD4.

In an embodiment, the formation of the first to fourth photoelectric conversion regions PD1 to PD4 may include injecting impurities, which may be of a second conductivity type (e.g., n-type) different from the first conductivity type (e.g., p-type), into the substrate 100.

A thinning process may be performed on the second surface 100b of the substrate 100 to remove a portion of the substrate 100 and a portion of the deep isolation pattern 150. In an embodiment, the thinning process may include grinding or polishing the second surface 100b of the substrate 100 and/or anisotropically and/or isotropically etching the second surface 100b of the substrate 100. As a result of the thinning process, a lower portion of the deep isolation pattern 150 may be removed, and the deep isolation pattern 150 may have a bottom surface that may be substantially coplanar with the second surface 100b of the substrate 100. The central intervening region CIR may be defined between the first and third photoelectric conversion regions PD1 and PD3. In an embodiment, the central intervening region CIR may be a DCC region.

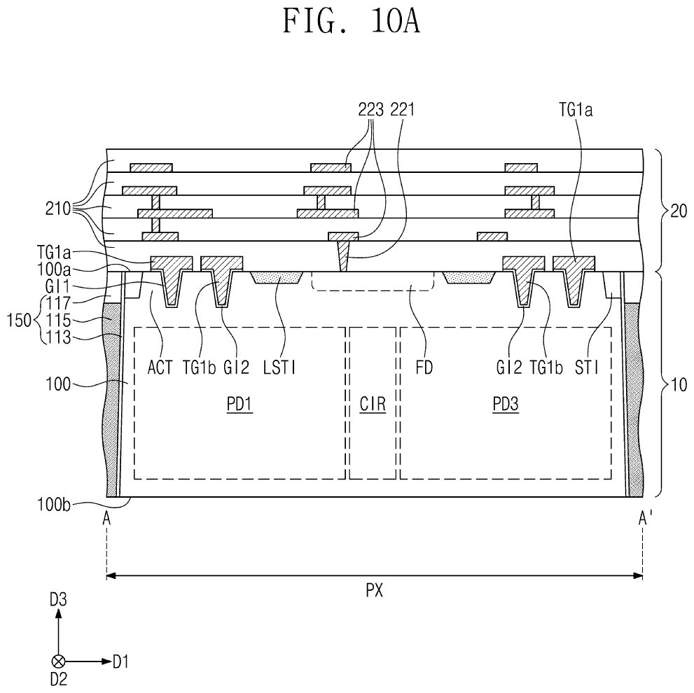

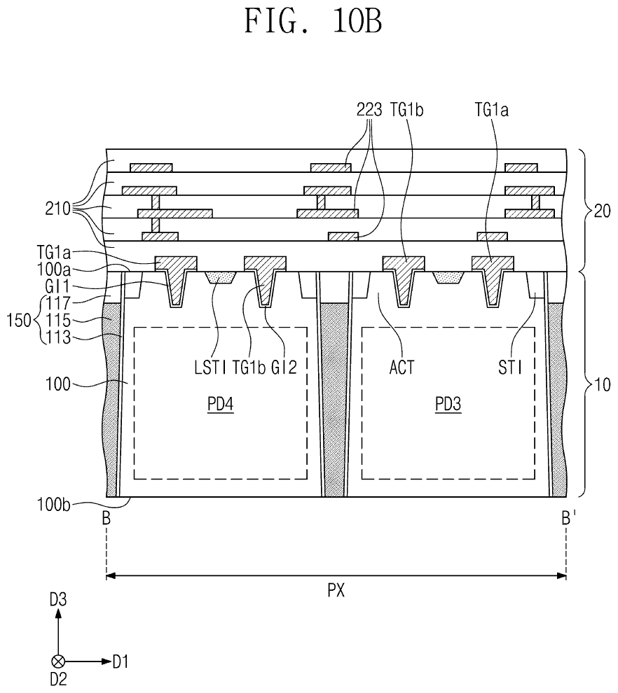

Referring to FIGS. 10A and 10B, the first and second transfer gate electrodes TG1a and TG1b and the floating diffusion region FD1 may be formed in each pixel region PX and may be adjacent to the first surface 100a of the substrate 100. The first and second transfer gate electrodes TG1a and TG1b may be formed on a corresponding one of the active patterns ACT, and the floating diffusion region FD may be formed to overlap with the photoelectric first to fourth conversion regions PD1 to PD4 and with the central intervening region CIR vertically (e.g., in the third direction D3). A lower portion of each of the first and second transfer gate electrodes TG1a and TG1b may be provided to penetrate a corresponding one of the active patterns ACT and may be extended into the substrate 100. An upper portion of each of the first and second transfer gate electrodes TG1a and TG1b may be provided to protrude above a top surface of a corresponding one of the active patterns ACT (e.g., the first surface 100a of the substrate 100). In an embodiment, the floating diffusion region FD may be formed by doping the corresponding one of the active patterns ACT with impurities, which may be of a second conductivity type (e.g., n-type) different from the first conductivity type of the substrate 100.

A first gate dielectric pattern GI1 may be formed between each of the first transfer gate electrodes TG1a and the substrate 100 (e.g., corresponding active pattern ACT), and a second gate dielectric pattern GI2 may be formed between each of the second transfer gate electrodes TG1b and the substrate 100 (e.g., corresponding active pattern ACT).

The interlayer insulating layers 210 and the interconnection structures 221 and 223 may be formed on the first surface 100a of the substrate 100. The interlayer insulating layers 210 may cover the transfer transistors and the logic transistors. The interlayer insulating layers 210 may be formed of a material having a good gap-filling property and may be formed to have a substantially flat top surface.

The contact plugs 221, which are connected to the floating diffusion region FD, may be formed in the interlayer insulating layers 210. The metal lines 223 may be formed between the interlayer insulating layers 210. The contact plugs 221 and the metal lines 223 may be formed of and/or may include at least one of, but not be limited to, copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), or alloys thereof.

Referring back to FIGS. 5A, 5B, and 5C, the planarization insulating layer 310 and the protection layer 312 may be sequentially formed on the second surface 100b of the substrate 100. The color filter 320 may be formed on the protection layer 312. The color filter 320 may include a plurality of color filters 320, which may be disposed on the pixel regions PX, respectively. Each of the plurality of color filters 320 may be formed to overlap with the first to fourth photoelectric conversion regions PD1 to PD4 of each pixel region PX vertically (e.g., in the third direction D3).

The lens insulating layer 322 may be formed on the color filter 320, and the micro lens 330 may be formed on the lens insulating layer 322. The micro lens 330 may include a plurality of micro lenses 330, and the micro lenses 330 may be disposed on the pixel regions PX, respectively. The micro lenses 330 may be formed to overlap with the first to fourth photoelectric conversion regions PD1 to PD4 of each pixel region PX vertically (e.g., in the third direction D3).

According to an embodiment of the present disclosure, a barrier device isolation pattern may be disposed between a floating diffusion region disposed in a pixel region and a transfer gate electrode disposed on a surface of a substrate and extended into a substrate. In such an embodiment, it may be possible to reduce a facing area between the transfer gate electrode and the floating diffusion region and thereby potentially improve a noise (pFPN). As a result, the electric characteristics of the image sensor may be improved, when compared to a related image sensor.

While example embodiments of the present disclosure have been particularly shown and described, it is to be understood by one of ordinary skill in the art that variations in form and detail may be made therein without departing from the spirit and scope of the attached claims.

What is claimed is:

1. An image sensor, comprising:
a substrate comprising a pixel region, a first surface, and a second surface opposite to the first surface;
a first photoelectric conversion region in the pixel region of the substrate;
a deep isolation pattern provided to at least partially penetrate the substrate and define the pixel region;
a first transfer gate electrode in the pixel region of the substrate and at least partially vertically overlapped with the first photoelectric conversion region, the first transfer gate electrode comprising a first upper portion, which protrudes above the first surface of the substrate, and a first lower portion, which is at least partially inserted into the substrate through the first surface of the substrate;
a floating diffusion region in the pixel region of the substrate and at least partially overlapped with the first photoelectric conversion region; and
a barrier device isolation pattern between the floating diffusion region and the first transfer gate electrode,
wherein the first transfer gate electrode is at least partially extended into the substrate,
wherein the barrier device isolation pattern is spaced apart from the first transfer gate electrode, and
wherein a central intervening region is provided in the substrate to be at least partially vertically overlapped with the floating diffusion region.

2. The image sensor of claim 1, further comprising:
a second transfer gate electrode at least partially vertically overlapped with the first photoelectric conversion region,
wherein the second transfer gate electrode comprises a second upper portion, which protrudes above the first surface of the substrate, and a second lower portion, which is at least partially inserted into the substrate through the first surface of the substrate,
wherein the second transfer gate electrode is spaced apart from the barrier device isolation pattern, and
wherein the barrier device isolation pattern is between the second transfer gate electrode and the floating diffusion region.

3. The image sensor of claim 1, further comprising:
a shallow isolation pattern provided to be in contact with the deep isolation pattern and define an active portion of the substrate,
wherein the shallow isolation pattern is spaced apart from the first transfer gate, and
wherein a level of a bottom surface of the barrier device isolation pattern is different from a level of a bottom surface of the shallow isolation pattern.

4. The image sensor of claim 1, further comprising:
a second photoelectric conversion region spaced apart from the first photoelectric conversion region in a first direction;
a first micro lens at least partially overlapped with the first photoelectric conversion region; and
a second micro lens at least partially overlapped with the second photoelectric conversion region,
wherein the deep isolation pattern is between the first photoelectric conversion region and the second photoelectric conversion region.

5. The image sensor of claim 1, further comprising:
a second photoelectric conversion region spaced apart from the first photoelectric conversion region in a first direction,
wherein the floating diffusion region is at least partially vertically overlapped with the first photoelectric conversion region and the second photoelectric conversion region.

6. The image sensor of claim 5, wherein a largest width of the floating diffusion region is larger than a width of the barrier device isolation pattern.

7. The image sensor of claim 5, further comprising:
a third photoelectric conversion region spaced apart from the second photoelectric conversion region in a second direction crossing the first direction; and
an isolation structure between the first photoelectric conversion region and the third photoelectric conversion region.

8. The image sensor of claim 7, wherein the isolation structure is at least partially overlapped with the floating diffusion region.

9. The image sensor of claim 1, further comprising:
a shallow isolation pattern provided to be in contact with the deep isolation pattern and define an active portion of the substrate,
wherein the shallow isolation pattern and the barrier device isolation pattern comprise different materials from each other.

10. An image sensor, comprising:
a substrate comprising a pixel region;
a first photoelectric conversion region in the pixel region of the substrate;
a deep isolation pattern provided to at least partially penetrate the substrate and at least partially enclose the pixel region;
a shallow isolation pattern provided to be in contact with the deep isolation pattern and define an active portion of the substrate;
a first transfer gate electrode and a second transfer gate electrode in the pixel region of the substrate and at least partially vertically overlapped with the first photoelectric conversion region;
a floating diffusion region at least partially overlapped with the first photoelectric conversion region; and
a barrier device isolation pattern between the floating diffusion region and the first transfer gate electrode and the second transfer gate electrode,
wherein the barrier device isolation pattern is spaced apart from the first transfer gate electrode and the second transfer gate electrode, and
wherein a level of a bottom surface of the barrier device isolation pattern is higher than a level of a bottom surface of the shallow isolation pattern.

11. The image sensor of claim 10, wherein the level of the bottom surface of the barrier device isolation pattern is higher than a level of a bottom surface of the first transfer gate electrode.

12. The image sensor of claim 10, further comprising:
a second photoelectric conversion region spaced apart from the first photoelectric conversion region in a first direction,
wherein the floating diffusion region is at least partially overlapped with the first photoelectric conversion region and the second photoelectric conversion region.

13. The image sensor of claim 12, further comprising:
a third photoelectric conversion region spaced apart from the second photoelectric conversion region in a second direction crossing the first direction; and
a micro lens on the substrate,
wherein the micro lens is at least partially overlapped with the first photoelectric conversion region, the second photoelectric conversion region, and the third photoelectric conversion region.

14. The image sensor of claim 13, further comprising:
an isolation structure between the first photoelectric conversion region and the third photoelectric conversion region,
wherein the isolation structure is at least partially overlapped with the floating diffusion region.

15. The image sensor of claim 10, further comprising:
a second photoelectric conversion region spaced apart from the first photoelectric conversion region in a first direction;
a first micro lens at least partially overlapped with the first photoelectric conversion region; and
a second micro lens at least partially overlapped with the second photoelectric conversion region,
wherein the deep isolation pattern is between the first photoelectric conversion region and the second photoelectric conversion region.

16. The image sensor of claim 10, wherein the shallow isolation pattern and the barrier device isolation pattern comprise different materials from each other.

17. An image sensor, comprising:
a substrate comprising a plurality of pixel regions, a first surface, and a second surface opposite to the first surface;
a transfer gate electrode in the first surface of the substrate and at least partially extended into the substrate;
a plurality of photoelectric conversion regions provided in the plurality of pixel regions;
a micro lens provided on the first surface and at least partially overlapped with the plurality of photoelectric conversion regions;
a deep isolation pattern interposed between the plurality of pixel regions and at least partially extended from the first surface into the substrate;
a shallow isolation pattern provided to be in contact with the deep isolation pattern and define an active portion of the substrate;
a floating diffusion region in the plurality of pixel regions and spaced apart from the plurality of photoelectric conversion regions;
a barrier device isolation pattern interposed between the floating diffusion region and the transfer gate electrode; and
an interconnection layer in the first surface of the substrate,
wherein the barrier device isolation pattern is spaced apart from the floating diffusion region, and
wherein a level of a bottom surface of the barrier device isolation pattern is lower than a level of a bottom surface of the floating diffusion region.

18. The image sensor of claim 17, further comprising:
an isolation structure at least partially extended from the second surface toward the first surface,
wherein the isolation structure is at least partially overlapped with the floating diffusion region.

19. The image sensor of claim 17, wherein the level of the bottom surface of the barrier device isolation pattern is higher than a level of a bottom surface of the shallow isolation pattern.

20. The image sensor of claim 17, wherein the plurality of photoelectric conversion regions comprises:
a first photoelectric conversion region, and
a second photoelectric conversion region spaced apart from the first photoelectric conversion region in a first direction,
wherein the deep isolation pattern is between the first photoelectric conversion region and the second photoelectric conversion region.
